(19) United States
(12) Patent Application Publication
(10) Pub. No.: US 2012/0192037 A1
(43) Pub. Date: Jul. 26, 2012

(54) DATA STORAGE SYSTEMS AND METHODS HAVING BLOCK GROUP ERROR CORRECTION FOR REPAIRING UNRECOVERABLE READ ERRORS

(75) Inventors: Garth A. GIBSON, Pittsburgh, PA (US); Ed GRONKE, Portland, OR (US); Brent B. Welch, Mountain View, CA (US)

(73) Assignee: Panasas, Inc.

(21) Appl. No.: 13/436,168

(22) Filed: Mar. 30, 2012

Related U.S. Application Data
(63) Continuation of application No. 12/219,323, filed on Jul. 18, 2008, now abandoned.
(60) Provisional application No. 60/950,433, filed on Jul. 18, 2007.

(51) Int. Cl. H03M 13/05; G06F 11/10

(52) U.S. Cl. 714/769; 714/E11.034

(57) ABSTRACT

Data storage systems and methods perform error correction on a single physical storage disk. The technique includes arranging a plurality of addressable blocks on the single physical storage disk into error correction groups, wherein each error correction group includes N data blocks and M coding blocks. M is determined in accordance with a desired failure tolerance of the error correction groups and an error-correcting code. For each error correction group, error-correcting code data is computed across the N data blocks in the error correction group. The computed error-correcting coding data is stored in the M coding blocks in the error correcting group. The arranging, computing and storing steps are performed by a hardware or software component external to the single physical storage disk.

This application is a continuation of copending U.S. application Ser. No. 12/219,323, filed Jul. 18, 2008 which is hereby incorporated herein by reference in its entirety. This application claims the benefit of priority under 35 U.S.C. §119(e) based on U.S. provisional application No. 60/950,433, filed on Jul. 18, 2007, which is incorporated herein in its entirety.

### FIELD OF THE INVENTION

The present invention is directed to data storage systems and methods having block group error correction for facilitating file reconstruction and restoration.

### BACKGROUND OF THE INVENTION

With increasing reliance on electronic means of data communication, different models to efficiently and economically store a large amount of data have been proposed. In a traditional networked storage system, a data storage device, such as a hard disk, is associated with a server or a server having a backup server. Access to the data storage device is available only through the server associated with that data storage device. A client processor desiring access to the data storage device would, therefore, access the associated server through the network and the server would access the data storage device as requested by the client. By contrast, in an object-based data storage system, each object-based storage device communicates directly with clients over a network. An example of an object-based storage system is shown in commonly-owned, U.S. Pat. No. 6,985,995, titled “Data File Migration from a Mirrored RAID to a Non-Mirrored XOR-Based RAID Without Rewriting the Data,” incorporated by reference herein in its entirety.

The data on each hard disk is typically stored in “blocks”, each of which contains a number of disk sectors to store the incoming data. In other words, the total physical disk space is divided into “blocks” and “sectors” to store data. However, data stored on disks are subject to various types of storage errors. For example, a catastrophic disk failure may be result in the loss of all, or substantially all, data stored on the disk. Disk errors may also be localized, resulting in the loss of data from isolated areas of the disk, perhaps as small as a single sector. Other read errors may be detected and corrected by the disk reading mechanism, for example, by retrying the operation, and result only in performance degradation.

Data storage systems may have a level of fault tolerance or redundancy to preserve data integrity in the event of one or more disk failures. One group of schemes for fault tolerant data storage is the RAID (Redundant Array of Independent Disks) levels or configurations. A number of RAID levels (e.g., RAID-0, RAID-1, RAID-3, RAID-4, RAID-5, etc.) are designed to provide fault tolerance and redundancy for different data storage applications. RAID-1 employs “mirroring” of data to provide fault tolerance and redundancy. In other words, the contents of each primary disk are mirrored onto a corresponding secondary or mirror disk. The storage mechanism provided by RAID-1 is not the most economical or most efficient fault tolerance scheme. Although RAID-1 storage systems are simple to design and provide 100% redundancy (and, hence, increased reliability) during disk failures, RAID-1 systems substantially increase the storage overhead because of the necessity to mirror everything. Redundancy under RAID-1 may exist at every level of the system—from power supplies to disk drives to cables and storage controllers—to achieve full mirroring and steady availability of data during disk failures.

On the other hand, RAID-5 allows for reduced overhead and higher efficiency, albeit at the expense of increased complexity in the storage controller design and time-consuming data rebuilds when a disk failure occurs. RAID-5 uses the concepts of “parity” and “striping” to provide redundancy and fault tolerance. Simply speaking, “parity” can be thought of as a binary checksum or a single bit of information that the operator can use to tell if all the other corresponding data bits are likely correct. RAID-5 creates blocks of parity, where each bit in a parity block corresponds to the parity of the corresponding data bits in other associated blocks. The parity data is used to reconstruct blocks of data read from a failed disk drive. Furthermore, RAID-5 uses the concept of “striping”, which means that two or more disks store and retrieve data in parallel, thereby accelerating performance of data read and write operations. To achieve striping, the data is stored in different blocks on different drives. A single group of blocks and their corresponding parity block may constitute a single “stripe” within the RAID set. In RAID-5 configuration, the parity blocks are distributed throughout all the disk drives, instead of storing all the parity blocks on a single disk, which is RAID-4.

RAID was originally introduced to handle catastrophic drive failure. After a failure, the complete contents of the failed drive can be rebuilt from the redundant information on the other drives. As drive capacities have increased, nearly doubling in capacity every year, another common error source is the failure to read individual sectors from an otherwise healthy disk. These errors are caused by defects in the recording media or recording faults, and are called “unrecoverable read errors” or “uncorrectable read errors” because the error correction codes on the drive are unable to correct the problem and the read operation fails. Moreover, while disk drive capacities have increased rapidly, the rate of uncorrectable read errors (UREs) has remained constant, at approximately 1 error per 10¹⁴ to 10¹⁵ bits read. When used in a RAID configuration, the amount of data read from the surviving drives by the rebuild process following a catastrophic drive failure is proportional to the capacity of the lost device. As disk drive capacities increase, the amount of data read from surviving drives increases at roughly the same rate. The implication of these trends is that the chances of encountering a URE during a RAID rebuild is also increasing, at approximately the same rate as drive capacity is increasing. When this occurs, some amount of data in a single failure correcting RAID array (ranging in size from a stripe to the entire array, depending on the implementation of the RAID controller) is irretrievably lost, leading to an indication being returned to the original requester (a user or application) that the data requested is unrecoverable. Such an application/user-visible failure may involve, for example, the interruption of computing service, the need to restore data from back-up copies, and/or the loss of some previously written data.

Various mitigating schemes have been devised for detecting latent errors before they cause an error during a rebuild. The latent errors may include UREs. These mostly revolve around periodically “scrubbing” the disk by attempting to read every sector and correcting any errors that are found, using RAID parity bits. However, these methods are expensive in terms of disk utilization and at best achieve a reduction in the frequency of user/application-visible errors. The lack of an effective technique for correcting the combination of a failed disk drive and a URE during rebuild has led to the industry adoption of two-fault-tolerant RAID schemes. These schemes are known collectively as RAID-6. However, these schemes suffer from common problems. For example, RAID-6 doubles the parity overhead for the array, reducing usable capacity. Moreover, every update to the array requires updating two parity blocks on two different disks, reducing throughput. In addition, the amount of data that must be written to gain the performance advantages of a full stripe write is usually significantly larger to amortize the capacity overhead, which reduces throughput further for workloads that are not purely sequential. Further, as noted above, the reading mechanism may be able to detect and correct some read errors. However, there are a host of read errors that are not detectable or correctable by the reading mechanism.

Hence, it is desirable to construct a mechanism for correcting unrecoverable read errors that does not suffer from the drawbacks characteristic of RAID-6.

### SUMMARY OF THE INVENTION

In one embodiment, a method for performing error correction on a single physical storage disk is provided. The method includes arranging a plurality of addressable blocks on the single physical storage disk into error correction groups, wherein each error correction group comprises N data blocks and M coding blocks, and for each error correction group; computing, in accordance with the error-correcting code, error-correcting coding data across the N data blocks in the error correction group; and storing the computed error-correcting coding data in the M coding blocks in the error correcting group. The arranging, computing and storing steps are performed by a hardware or software component external to the single physical storage disk. The error-correcting coding data may correspond to XOR-based parity data.

The method may further include receiving an error message if the single physical storage disk is unable to read one or more failed data or coding blocks associated with a given error correction group; in response to the error message, attempting to read a remainder of the data and coding blocks in the given error correction group; and if a sufficient number of the remainder of the data and coding blocks and coding blocks are successfully read, computing a corrected version of the one or more failed data or coding blocks from at least part of the remainder of the data and the coding blocks.

Moreover, the method may further comprise using the corrected version of the one or more failed data or coding blocks to rewrite an unreadable addressable block, optionally to a spare addressable block on the single physical storage disk, thereby repairing a fault associated with the error message.

By way of example, M may equal to one and N may be selected from the group consisting of: 8, 16 and 256. Moreover, the error-correcting coding data may correspond to Reed-Solomon data, and N and M are selected from the group consisting of: N=8 and M=2; N=16 and M=2; N=64 and M=2; and N=256 and M=4.

The method may further include detecting a silent read error by reading, from the disk, data and coding blocks associated with a given error correction group; computing an expected value of the one or more coding blocks from the data blocks read from the disk; and comparing the expected value to the one or more coding blocks read from the disk, wherein a silent read error is identified if the computed value does not match the one or more coding blocks read from the disk. If a silent error is detected, the correct data may be reconstructed from redundant data on other storage disks.

The method may also include storing the K*N data blocks of K error correction groups contiguously, followed by K*M coding blocks associated with said K*N data blocks. For example, K may equal 4, N may equal 8, and exclusive OR (XOR) parity may be used as the error-correcting code.

The method may include logically arranging the N data blocks in each error correction group into a rectangular array having rows and columns, and computing the error correcting code across both the rows and columns of the array. In addition, the method may include interleaving the data blocks and coding blocks from K error correction groups, such that consecutive addressable blocks on the physical disk contain data or coding blocks from different error correction groups. Both the data blocks and coding blocks from each error correction group may be transmitted to a host or client machine which is an end-user of the data represented by the error correction groups. Moreover, M may be determined in accordance with a desired failure tolerance of the error correction groups and an error-correcting code.

In another instance, a method for recovering data from a physical storage device in the event of a read error is provided. The storage device stores data organized in a plurality of correction groups, each correction group comprising a plurality of addressable blocks for storing data and an addressable block for storing error-correcting code coding information corresponding to the data of the plurality of blocks of the correction group. The method comprising includes attempting to read data contents of a selected addressable block of the storage device; if a read error of the physical storage device occurs preventing the selected addressable block from being properly read, then reading the contents of the correction group to which the selected addressable block belongs; and computing correct data of the selected addressable block using the data contents of the remainder of the addressable blocks of the correction group and error-correcting code information of the correction group.

The method may include storing the computed correct data in another addressable block. The method may also include attempting to read the data contents of multiple addressable blocks of the storage device, including the selected addressable block.

In another instance, a method for detecting silent read errors of data stored in a selected addressable block of a physical storage device is provided. The storage device stores data organized in a plurality of correction groups, each correction group comprising a plurality of addressable blocks for storing data and an addressable block for storing error-correcting code coding information corresponding to the stored data of the plurality of blocks of the correction group. The method includes reading data contents of a correction group corresponding to the selected addressable block from the storage device, the data contents including stored data of addressable blocks of the correction group and error-correcting code information of the correction group; computing error-correcting code information using the data of the plurality of addressable blocks of the correction group; comparing the computed error-correcting code information to the error-correcting code information read from storage device; and indicating a silent read error if the computed error-correcting code information does not match the error-correcting code information read from storage device.

### BRIEF DESCRIPTION OF THE DRAWINGS

The accompanying drawings, which are included to provide a further understanding of the invention and are incorporated in and constitute a part of this specification, illustrate embodiments of the invention that together with the description serve to explain the principles of the invention. In the drawings:

FIG. 1 illustrates an embodiment of an exemplary data storage network.

FIG. 2 illustrates another embodiment of a data storage system network.

FIG. 3 illustrates a block diagram of an exemplary data storage system.

FIG. 4 provides a conceptual rendering of a correction group mapping arrangement of addressable blocks of a storage device.

FIG. 5 provides a conceptual rendering of a second correction group mapping arrangement of addressable blocks of a storage device.

FIG. 6 provides an exemplary process flow of operations of a data driver and storage device in the event that the storage device is unable to read the contents of a block.

FIG. 7 illustrates an exemplary process flow of operations of a data driver and storage device for detecting silent read errors.

FIG. 8 provides a conceptual rendering of a further correction group mapping arrangement of addressable blocks of a storage device.

FIG. 9 provides a conceptual rendering of a further correction group mapping arrangement of addressable blocks of a storage device

### DETAILED DESCRIPTION OF THE PREFERRED EMBODIMENTS

Reference will now be made in detail to the preferred embodiments of the present invention, examples of which are illustrated in the accompanying drawings. It is to be understood that the figures and descriptions of the present invention included herein illustrate and describe elements that are of particular relevance to the present invention, while eliminating, for purposes of clarity, other elements found in typical data storage systems or networks.

It is worthy to note that any reference in the specification to “one embodiment” or “an embodiment” means that a particular feature, structure or characteristic described in connection with the embodiment is included in at least one embodiment of the invention. The appearances of the phrase “in one embodiment” at various places in the specification do not necessarily all refer to the same embodiment.

Embodiments set forth below correspond to examples of object-based data storage implementations of the present invention. However, the various teachings of the present invention can be applied in object-based data storage systems as well as other data storage systems.

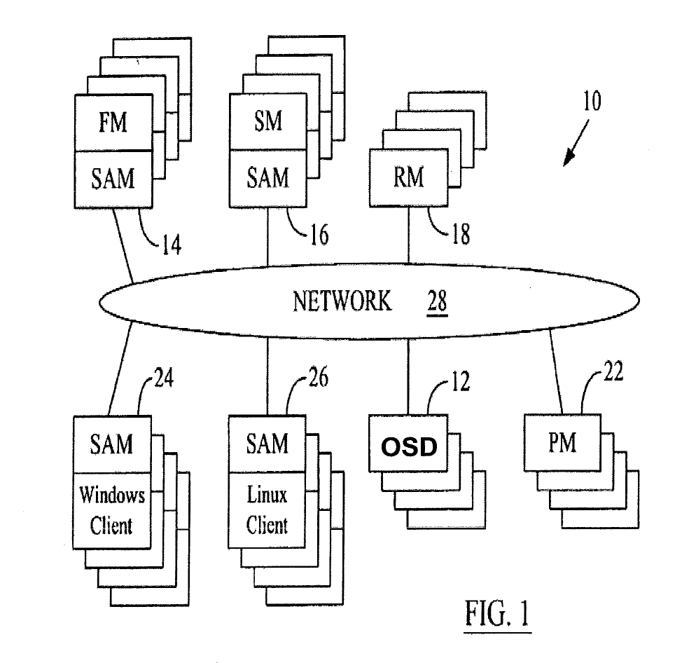

FIG. 1 illustrates an exemplary data storage network 10. It should be appreciated that data storage network 10 is intended to be illustrative structure useful for the description herein. In this embodiment, the data storage network 10 is a network-based system designed around data storage systems 12. The data storage systems 12 may be, for example, Object Based Secure Disks (OSDs or OBDs). However, this is intended to be an example. The principles described herein may be used in non-network based storage systems and/or may be used in storage systems that are not object-based, such as block-based systems or file-based systems.

The data storage network 10 is implemented via a combination of hardware and software units and generally consists of managers 14, 16, 18, and 22, data storage systems 12, and clients 24, 26. It is noted that FIG. 1 illustrates multiple clients, data storage systems, and managers operating in the network environment. However, for the ease of discussion, a single reference numeral is used to refer to such entity either individually or collectively depending on the context of reference. For example, the reference numeral “12” is used to refer to just one data storage system or multiple data storage systems depending on the context of discussion. Similarly, the reference numerals 14 and 22 for various managers are used interchangeably to also refer to respective servers for those managers. For example, the reference numeral “14” is used to interchangeably refer to the software file managers (FM) and also to their respective servers depending on the context. It is noted that each manager is an application program code or software running on a corresponding hardware, such as a server. Moreover, server functionality may be implemented with a combination of hardware and operating software. For example, each server in FIG. 1 may be a Windows NT server. Thus, the data storage network 10 in FIG. 1 may be, for example, an object-based distributed data storage network implemented in a client-server configuration.

The network 28 may be a LAN (Local Area Network), WAN (Wide Area Network), MAN (Metropolitan Area Network), SAN (Storage Area Network), wireless LAN, or any other suitable data communication network, or combination of networks. The network may be implemented, in whole or in part, using a TCP/IP (Transmission Control Protocol/Internet Protocol) based network (e.g., the Internet). A client 24, 26 may be any computer (e.g., a personal computer or a workstation) coupled to the network 28 and running appropriate operating system software as well as client application software designed for the network 10. FIG. 1 illustrates a group of clients or client computers 24 running on Microsoft Windows operating system, whereas another group of clients 26 are running on the Linux operating system. The clients 24, 26 thus present an operating system-integrated file system interface. The semantics of the host operating system (e.g., Windows, Linux, etc.) may preferably be maintained by the file system clients.

The manager (or server) and client portions of the program code may be written in C, C++, or in any other compiled or interpreted language suitably selected. The client and manager software modules may be designed using standard software tools including, for example, compilers, linkers, assemblers, loaders, bug tracking systems, memory debugging systems, etc.

In one embodiment, the manager software and program codes running on the clients may be designed without knowledge of a specific network topology. In such case, the software routines may be executed in any given network environment, imparting software portability and flexibility in storage system designs. However, it is noted that a given network topology may be considered to optimize the performance of the software applications running on it. This may be achieved without necessarily designing the software exclusively tailored to a particular network configuration.

FIG. 1 shows a number of data storage systems 12 attached to the network 28. The data storage systems 12 store data for a plurality of volumes. The data storage systems 12 may implement a block-based storage method, a file-based method, an object-based method, or another method. Examples of block-based methods included parallel Small Computer System Interface (SCSI) protocols, Serial Attached SCSI (SAS) protocols, and Fiber Channel SCSI (FCP) protocols, among others. An example of an object-based method is the ANSI T10 OSD protocol. Examples of file-based methods include Network File System (NFS) protocols and Common Internet File Systems (CIFS) protocols, among others.

In some storage networks, a data storage device, such as a hard disk, is associated with a particular server or a particular server having a particular backup server. Thus, access to the data storage device is available only through the server associated with that data storage device. A client processor desiring access to the data storage device would, therefore, access the associated server through the network and the server would access the data storage device as requested by the client.

Alternatively, each data storage system 12 may communicate directly with clients 24, 26 on the network 28, possibly through routers and/or bridges. The data storage systems, clients, managers, etc., may be considered as “nodes” on the network 28. In storage system network 10, no assumption needs to be made about the network topology (as noted hereinbefore) except that each node should be able to contact every other node in the system. The servers (e.g., servers 14, 16, 18, etc.) in the network 28 merely enable and facilitate data transfers between clients and data storage systems, but the servers do not normally implement such transfers.

In one embodiment, the data storage systems 12 themselves support a security model that allows for privacy (i.e., assurance that data cannot be eavesdropped while in flight between a client and a data storage system), authenticity (i.e., assurance of the identity of the sender of a command), and integrity (i.e., assurance that in-flight data cannot be tampered with). This security model may be capability-based. A manager grants a client the right to access the data stored in one or more of the data storage systems by issuing to it a “capability.” Thus, a capability is a token that can be granted to a client by a manager and then presented to a data storage system to authorize service. Clients may not create their own capabilities (this can be assured by using known cryptographic techniques), but rather receive them from managers and pass them along to the data storage systems.

Logically speaking, various system “agents” (i.e., the clients 24, 26, the managers 14, 22 and the data storage systems 12) are independently-operating network entities. Day-to-day services related to individual files and directories are provided by file managers (FM) 14. The file manager 14 may be responsible for all file- and directory-specific states. In this regard, the file manager 14 may create, delete and set attributes on entities (i.e., files or directories) on clients' behalf When clients want to access other entities on the network 28, the file manager performs the semantic portion of the security work—i.e., authenticating the requester and authorizing the access—and issuing capabilities to the clients. File managers 14 may be configured singly (i.e., having a single point of failure) or in failover configurations (e.g., machine B tracking machine A's state and if machine A fails, then taking over the administration of machine A's responsibilities until machine A is restored to service).

The primary responsibility of a storage manager (SM) 16 is the aggregation of data storage systems 12 for performance and fault tolerance. “Aggregate” objects are objects that use data storage systems in parallel and/or in redundant configurations, yielding higher availability of data and/or higher I/O performance. Aggregation is the process of distributing a single data file or file directory over multiple data storage system objects, for purposes of performance (parallel access) and/or fault tolerance (storing redundant information). The aggregation scheme associated with a particular object may optionally be stored as an attribute of that object on a data storage system 12. A system administrator (e.g., a human operator or software) may choose any layout or aggregation scheme for a particular object. The SM 16 may also serve capabilities allowing clients to perform their own I/O to aggregate objects (which allows a direct flow of data between a data storage system 12 and a client). The storage manager 16 may also determine exactly how each object will be laid out—i.e., on what data storage system or systems that object will be stored, whether the object will be mirrored, striped, parity-protected, etc. This distinguishes a “virtual object” from a “physical object”. One virtual object (e.g., a file or a directory object) may be spanned over, for example, three physical objects (i.e., multiple data storage systems 12 or multiple data storage devices of a data storage system 12). In one embodiment, a new file or directory inherits the aggregation scheme of its immediate parent directory, by default. Storage Manager 16 may be allowed to make layout changes for purposes of load or capacity balancing.

The storage manager 16 may also allow clients to perform their own I/O to aggregate objects (which allows a direct flow of data between a data storage system and a client), as well as providing proxy service when needed. As noted earlier, individual files and directories in the file system network 10 may be represented by unique storage systems objects. Manager 16 may also determine exactly how each object will be laid out—i.e., on which data storage system(s) that object will be stored, whether the object will be mirrored, striped, parity-protected, etc. Manager 16 may also provide an interface by which users may express minimum requirements for an object's storage (e.g., “the object must still be accessible after the failure of any one data storage system”).

Each manager may be a separable component in the sense that the manager may be used for other file system configurations or data storage system architectures. In one embodiment, the topology for the system network 10 may include a “file system layer” abstraction and a “storage system layer” abstraction. The files and directories in the system network 10 may be considered to be part of the file system layer, whereas data storage functionality (involving the data storage systems 12) may be considered to be part of the storage system layer. In one topological model, the file system layer may be on top of the storage system layer.

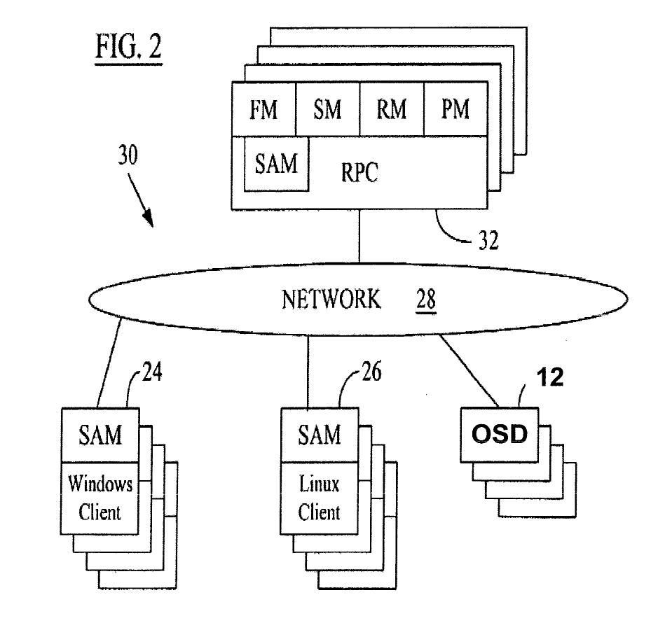

The storage access module (SAM) is a program code module that may be compiled into the managers as well as the clients. The SAM may include an I/O execution engine that implements simple I/O, mirroring, and map retrieval algorithms. The SAM generates and sequences the data storage system-level operations necessary to implement system-level I/O operations, for both simple and aggregate objects. A performance manager 22 may run on a server that is separate from the servers for other managers (as shown, for example, in FIG. 1) and may be responsible for monitoring the performance of the data storage realm and for tuning the locations of objects in the system to improve performance. The program codes for managers typically communicate with one another via RPC (Remote Procedure Call) even if all the managers reside on the same node (as, for example, in the configuration in FIG. 2).

Each manager 10 may maintain global parameters, notions of what other managers are operating or have failed, and provides support for up/down state transitions for other managers. A benefit to the present system is that the location information describing at what data storage system 12 (e.g., OSD) or systems the desired data is stored may optionally be located at a plurality of data storage systems in the network. In such an embodiment, a client 30 need only identify one of a plurality of data storage systems 12 containing location information for the desired data to be able to access that data. The data may be returned to the client directly from the data storage systems 12 without passing through a manager.

A further discussion of various managers shown in FIG. 1 (and FIG. 2) and the interaction among them is provided in the commonly-owned U.S. Pat. No. 6,985,995, whose disclosure is incorporated by reference herein in its entirety.

The installation of the manager and client software to interact with data storage systems 12 and perform object-based data storage in the file system 10 may be called a “realm.” The realm may vary in size, and the managers and client software may be designed to scale to the desired installation size (large or small). A realm manager 18 is responsible for all realm-global states. That is, all states that are global to a realm state are tracked by realm managers 18. A realm manager 18 maintains global parameters, notions of what other managers are operating or have failed, and provides support for up/down state transitions for other managers. Realm managers 18 keep such information as realm-wide file system configuration, and the identity of the file manager 14 responsible for the root of the realm's file namespace. A state kept by a realm manager may be replicated across all realm managers in the data storage network 10, and may be retrieved by querying any one of those realm managers 18 at any time. Updates to such a state may only proceed when all realm managers that are currently functional agree. The replication of a realm manager's state across all realm managers allows making realm infrastructure services arbitrarily fault tolerant—i.e., any service can be replicated across multiple machines to avoid downtime due to machine crashes.

The realm manager 18 identifies which managers in a network contain the location information for any particular data set. The realm manager assigns a primary manager (from the group of other managers in the data storage network 10) which is responsible for identifying all such mapping needs for each data set. The realm manager also assigns one or more backup managers (also from the group of other managers in the system) that also track and retain the location information for each data set. Thus, upon failure of a primary manager, the realm manager 18 may instruct the client 24, 26 to find the location data for a data set through a backup manager.

FIG. 2 illustrates one implementation 30 where various managers shown individually in FIG. 1 are combined, for example, in a single binary file 32. FIG. 2 also shows the combined file available on a number of servers 32. In the embodiment shown in FIG. 2, various managers shown individually in FIG. 1 are replaced by a single manager software or executable file that can perform all the functions of each individual file manager, storage manager, etc. It is noted that all the discussion given hereinabove and later hereinbelow with reference to the data storage network 10 in FIG. 1 equally applies to the data storage network 30 illustrated in FIG. 2. Therefore, additional reference to the configuration in FIG. 2 is omitted throughout the discussion, unless necessary.

Generally, the clients may directly read and write data, and may also directly read metadata. The managers, on the other hand, may directly read and write metadata. Metadata may include, for example, file object attributes as well as directory object contents, group inodes, object inodes, and other information. The managers may create other objects in which they can store additional metadata, but these manager-created objects may not be exposed directly to clients.

In some embodiments, clients may directly access data storage systems 12, rather than going through a server, making I/O operations in the object-based data storage networks 10, 30 different from some other file systems. In one embodiment, prior to accessing any data or metadata, a client must obtain (1) the identity of the data storage system(s) 12 on which the data resides and the object number within the data storage system(s), and (2) a capability valid on the data storage systems(s) allowing the access. Clients may learn of the location of objects by directly reading and parsing directory objects located on the data storage system(s) identified. Clients obtain capabilities by sending explicit requests to file managers 14. The client includes with each such request its authentication information as provided by the local authentication system. The file manager 14 may perform a number of checks (e.g., whether the client is permitted to access the data storage system, whether the client has previously misbehaved or “abused” the system, etc.) prior to granting capabilities. If the checks are successful, the FM 14 may grant requested capabilities to the client, which can then directly access the data storage system in question or a portion thereof. Additional details regarding network communications and interactions, commands and responses thereto, among other information, may be found in U.S. Pat. No. 7,007,047, which is incorporated by reference herein in its entirety.

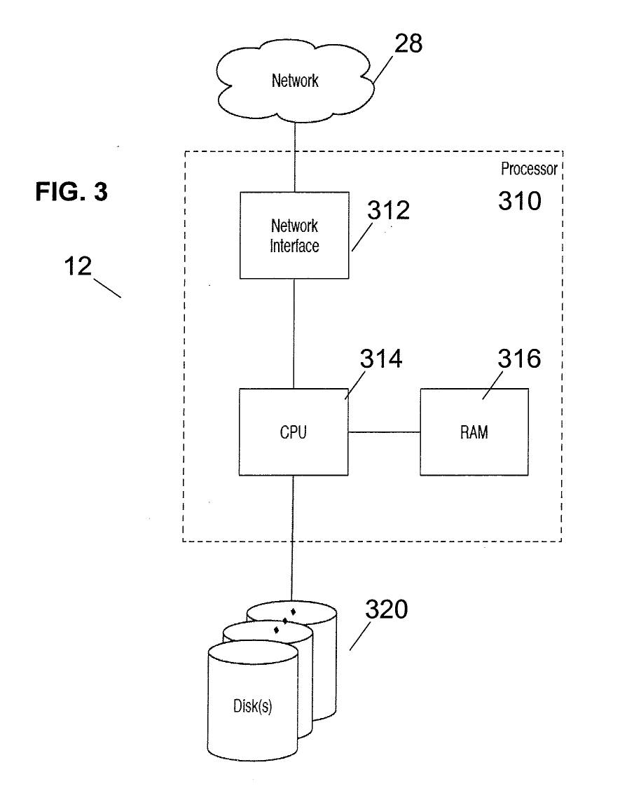

FIG. 3 illustrates an exemplary embodiment of a data storage system 12. As shown the data storage system 12 includes a processor 310 and one or more storage devices 320. The storage devices 320 may be storage disks that store data files in the network-based system 10. The storage devices 320 may be, for examples, hard drives, optical or magnetic disks, or other storage media, or combination of media. The processor 310 may be any type of processor, and may comprise multiple chips or a single system on a chip. If the data storage system 12 is utilized in a network environment, such as coupled to network 28, the processor 310 may be provided with network communications capabilities. For example, processor 310 may include a network interface 312, a CPU 314 with working memory, e.g., RAM 316. The processor 310 may also include ROM and/or other chips with specific applications or programmable applications. As discussed further below, the processor 310 manages data storage in the storage device(s) 320. The processor 310 may operate according to program code written in C, C++, or in any other compiled or interpreted language suitably selected. The software modules may be designed using standard software tools including, for example, compilers, linkers, assemblers, loaders, bug tracking systems, memory debugging systems, etc.

As noted, the processor 310 manages data storage in the storage devices. In this regard, it may execute routines to receive data and write that data to the storage devices and to read data from the storage devices and output that data to the network or other destination. The processor 310 also perform other storage-related functions, such as providing data regarding storage usage and availability, and creating, storing, updating and deleting metadata related to storage usage and organization, and managing data security.

The storage device(s) 320 may be divided into a plurality of blocks for storing data for a plurality of volumes. For example, the blocks may correspond to sectors of the data storage device(s) 320, such as sectors of one or more storage disks. The volumes may correspond to blocks of the data storage devices directly or indirectly. For example, the volumes may correspond to groups of blocks or a Logical Unit Number (LUN) in a block-based system, to object groups or object partitions of an object-based system, or files or file partitions of a file-based system. The processor 310 manages data storage in the storage devices 320. The processor may, for example, allocate a volume, modify a volume, or delete a volume. Data may be stored in the data storage system 12 according to one of several protocols.

As described herein, an error-correcting code is applied to a group of sectors or logical blocks on a single disk drive addressed by the disk drive interface software (such as, in a RAID controller or software RAID engine, or an OSD software stack on an object-based controller, or a disk device driver in an operating system or system library). This differs from the application of an error-correcting code to a RAID array, since in this case the code is applied over blocks from a single disk, rather than over blocks from multiple disks.

Described generally, the processor 310 operates as a disk device driver to arrange the addressable blocks on the raw storage disk device 320 into error correction groups, each of which may be a group of N data blocks and M coding blocks, and then computes an error-correcting code (such as XOR-based parity) over the N data blocks. The computed error-correcting code coding data is stored in the M additional blocks (coding blocks). N is referred to as the “block group size”. M may be determined based on the error correcting code used and the desired failure tolerance of the block group.

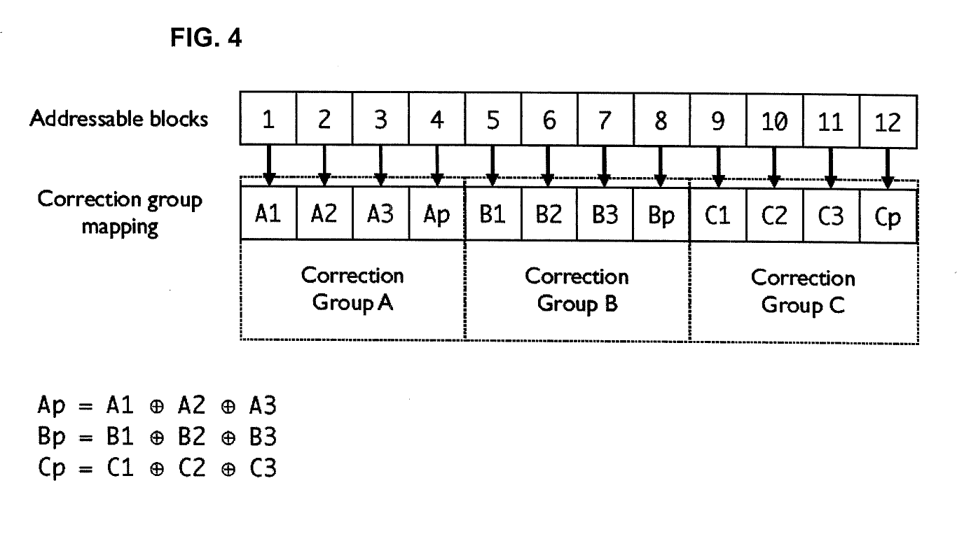

An example is illustrated in FIG. 4. FIG. 4 illustrates, by way of example, a conceptual rendering of 12 addressable blocks of a storage device 320. The use of 12 addressable blocks is intended to be illustrative and not limiting. A storage device 320 may include many more blocks. The 12 addressable blocks are organized by processor 310 into three Correction Groups A, B, and C. Correction Group A includes three addressable data blocks A1-A3 for storing data and an additional error correction block Ap. The content of error correction block Ap is defined, by way of example, as the exclusive OR of A1-A3 (i.e., Ap=A1 ⊕A2 ⊕A3). However, it should be appreciated that other error correction schemes may be used. Correction Groups B and C employ the same organization, as indicated in FIG. 4. Using the notation described above, the storage arrangement of FIG. 4 may be regarded as having three data blocks (N=3) and one additional coding block (M=1).

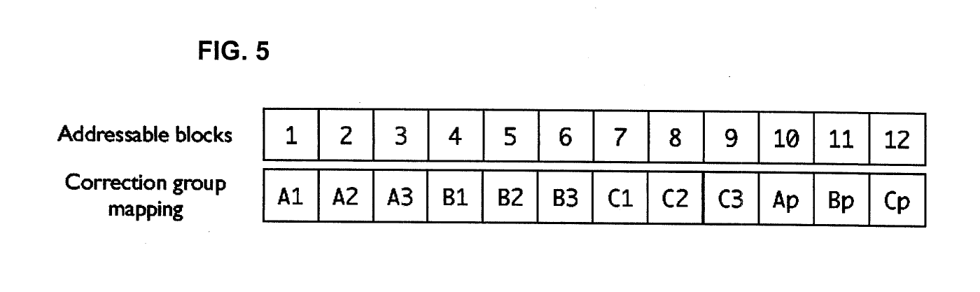

FIG. 5 illustrates a conceptual rendering of a further example of an arrangement of data and error correction code blocks in a data storage device 320. Similar to FIG. 4, the arrangement in FIG. 5 is illustrated with 12 addressable blocks. The addressable blocks include the three Correction Groups A, B and C. In this example, each of the Correction Groups include three addressable data blocks A1-A3, B1-B3, and C1-C3, respectively, and one error correction coding block Ap, Bp and Cp, respectively. However, in contrast to the arrangement in FIG. 4, FIG. 5 reflects that the addressable data blocks are separate from the addressable error correction coding blocks. For example, the addressable error correction coding blocks may be contiguous. The addressable data blocks may also be contiguous, or may be divided by the addressable error correction coding blocks. The arrangement shown in FIG. 5 may represent the arrangement of the entire storage device, or segments of the storage device. When data blocks from different Correction Groups are arranged contiguously, for example, as shown in FIG. 5, then multiple data blocks from the different Correction Groups may be read in a single transaction of the reading mechanism. Likewise, coding blocks from multiple Correction groups to be read together in a single transaction. Using FIG. 5 as an example, the data from Correction Groups B and C can be read together by the reading mechanism. Moreover, the coding blocks for Correction Groups B and C may be read together in the same or a separate transaction.

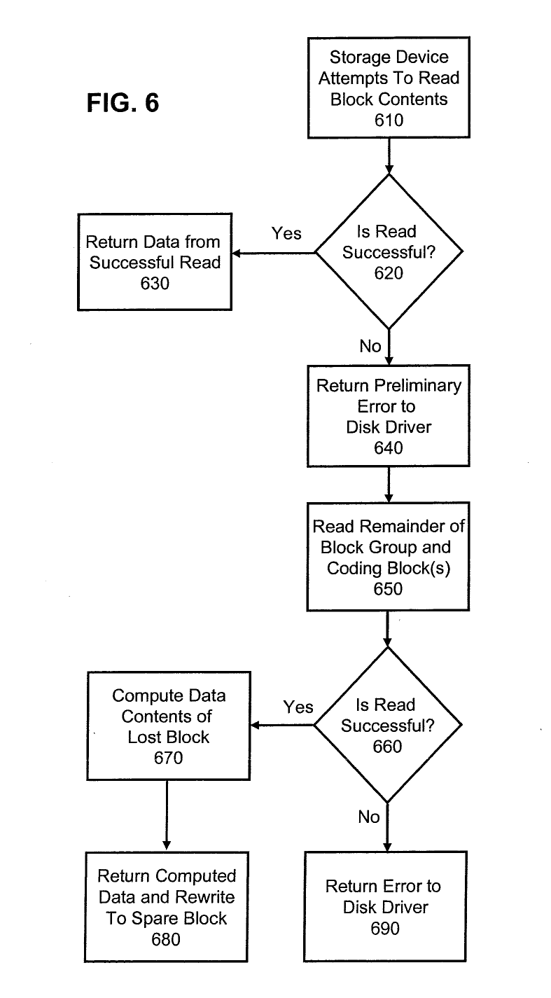

FIG. 6 illustrates an exemplary sequence in the event that the storage device 320 (such as a disk drive) is unable to read the contents of a block. The storage device first attempts to read the addressed block, as indicated at 610. At step 620, the storage device determines if the addressed block can be read. If so, the content of the addressed block is returned, as indicated at step 630. If not, the storage device at step 640 will return an error to the disk driver, such as processor 310. When the disk driver encounters this error, it will attempt to read the remainder of the correction group, including the coding blocks. This is indicated at step 650. The storage device determines if the read is successful at step 660. If a sufficient portion of the correction group has been successfully read, such that overall failure tolerance of the correction group has not been exceeded, the disk driver considers the overall read of the error correction group successful. The disk driver (e.g., processor 310) will compute the data contents of the lost block from the surviving data and coding blocks at step 670. At step 680, the disk driver will then return the requested data to the application and, in addition, the disk driver will use the computed data to rewrite the contents to one or more spare block(s) on the underlying storage device 320, thus repairing the fault. If the second read is not successful, then an error is returned, as indicated at step 690.

In accordance with the principles described herein, the size of the block group may be selected so as to balance capacity overhead, minimum update size, and the expected frequency and distribution of UREs. Large block groups amortize the overhead cost of the coding blocks over more data blocks, increasing the number of blocks that are usable for user data. However, each block group defines a URE “failure domain”, so the larger the block group, the higher the chances that multiple UREs will occur in the same block group and result in an unrecoverable failure. Moreover, a write that modifies a region of the disk smaller than the block group, or is not aligned on a block group boundary, will impose a read-modify-write style update that is less efficient than simply writing the new data and its coding block(s). For example, when using XOR parity as the error correcting code, writing less data than the full block group may require either reading the old data and parity, or reading the remainder of the block group, in order to compute the new contents of the coding block.

One possible implementation would use XOR (parity) as the error correcting code, with a block group size of 8 (N=8, M=1). Assuming a common disk sector size of 512 bytes, this would lead to a block group of 4 KB and error correcting code overhead of ( 1/9)=11%. These parameters would allow for recovery of any single URE in a group of eight sectors.

In addition to the N=8, M=1 encoding described above, there are other specific encodings that may be useful in common applications. These include:

(1) N=16, M=1, using parity as the error correcting code over 8 KB of data;

(2) N=256, M=1, using parity as the error correcting code parity over 128 KB of data;

(3) N=8, M=2, using Reed-Solomon as the error correcting code over 4 KB of data, which is tolerant of up to 2 failures in this region;

(4) N=16, M=2, using Reed-Solomon as the error correcting code over 8 KB of data, which is tolerant of up to 2 failures in this region;

(5) N=64, M=2, using Reed-Solomon as the error correcting code over 32 KB of data, which is tolerant of up to 2 failures in this region; and

(6) N=256, M=4, using Reed-Solomon as the error correcting code over 128 KB of data, which is tolerant of up to 4 failures in this region.

Any of these encodings may be combined with a block group interleaving technique in order to increase resilience to multiple failures on sequential disk blocks. The illustration of specific encodings should not be interpreted to limit the utility of this invention only to these example parameter values; other parameter values may be used with this algorithm depending on the I/O characteristics of the application and the desired tolerance for media defects.

In addition to unrecoverable read errors, in which the storage device, e.g., disk drive, signals an error rather than returning the requested data, storage devices also occasionally suffer from silent read errors. In a silent read error, the storage device returns data instead of an error status from a READ command, but the data does not match the expected contents. This can be due to a variety of causes, including returning the incorrect block (i.e., block 20 was requested but the drive returned the contents of block 21 instead) and random data corruption inside the storage device data path (e.g., bit-flip errors in the disk drive's cache memory). The error-correcting code described above can also be used to detect (and correct, in some cases) silent read errors.

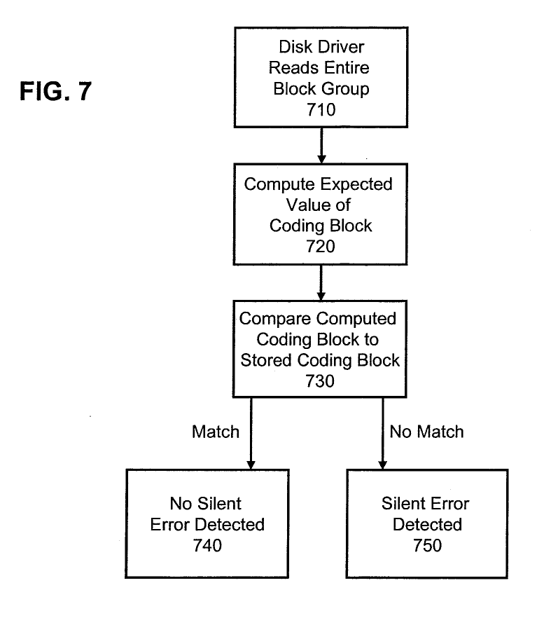

FIG. 7 illustrates an example of this use. As indicated at step 710, the disk driver reads an entire block group (both the data and coding blocks) whenever a block in that group is requested. The read operation may be executed by the disk driver sending a command to one or more of the storage devices and the storage device(s), responsive to the command, reads a region of the device storage media and provides at least the data content to the disk driver. The storage device(s) may also provide the stored error correction coding block corresponding to the data. At step 720, the disk driver computes the expected value of the coding block(s) from the data blocks read, and then at step 730 compares the computed coding block(s) to the actual coding block(s) read from the storage device. At step 740, no silent error is detected if the computed error correction code matches the stored error correction coding block. In contrast, at step 750, if a computed coding block does not match the corresponding coding block read from disk, this indicates that a silent read error has occurred. Depending on the characteristics of the error-correcting code used to construct the coding blocks, it may be possible to correct the error, or it may only be possible to detect that the error occurred. For example, when using an encoding that tolerates one fault, the system can recover from one failed read (URE) and can detect but not correct an inconsistency between the parity sector and the data. An inconsistency means that either the parity sector is wrong, or one of the data sectors is wrong, but a single-correction code cannot identify the incorrect sector. Encodings that tolerate more errors can identify sectors that are read successfully but contain incorrect data by cross checking with other redundant data. Specifically, if an error correction code can recover from 2 or more URE and recompute the missing data, it can identify a single sector that was read successfully but contained incorrect data. In general, an encoding that can correct N failed reads can identify N−1 sectors that were read successfully but contain incorrect data. Alternatively, a silent error may be corrected using redundant data stored on other storage disks.

Analysis of error patterns on real-world storage devices shows that bad blocks are not randomly and uniformly distributed. Instead, it is common for more than one block in the same region of the disk to go bad at the same time. This pattern is due to some of the underlying root causes of unrecoverable read errors (i.e., high-fly writes, particulate contamination, physical defects on the media, etc.) which affect more than one block in a small region of the disk. For this reason, an error-correction method which only allows recovery from a single block error in a contiguous sequence of logical blocks may not adequately address instances of UREs seen in the field.

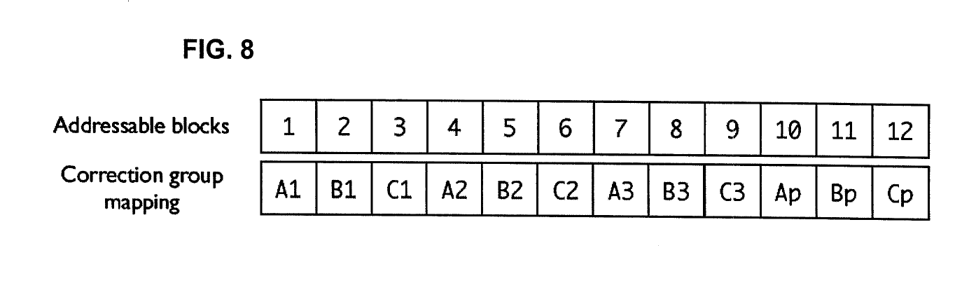

One solution to this is to use an error-correcting code which can tolerate a larger number of errors in a coding group (i.e., Reed-Solomon coding). However, these codes are often significantly more mathematically complex to compute than single-fault tolerant codes. Another solution is to interleave multiple block groups, such that blocks which are sequential on the disk belong to different block groups. A simple interleaved assignment of blocks to correction groups is shown, by way of example, in FIG. 8. As noted above in connection with FIGS. 4 and 5, the example of FIG. 8 is a conceptual illustration of data blocks of a storage device. While FIG. 8 shows 12 addressable blocks, the storage device may have more addressable blocks. FIG. 8 shows three Correction Groups A, B, and C, each having three data blocks (A1-A3, B1-B3, and C1-C3) and an error correcting coding block (Ap, Bp, and Cp). The data blocks and error correction coding blocks are interleaved on the storage device such that the elements of a given Correction Group are not contiguous with other elements of that Correction Group. Using an interleaved arrangement, a failure of multiple consecutive blocks (in this example, up to three consecutive blocks) can be repaired through the error-correcting code, since the blocks belong to different Correction Groups. In contrast, with respect to the arrangement shown in FIGS. 4 and 5, most failures of two consecutive blocks and all failures of three consecutive blocks will not be repairable, since they will affect two blocks from the same coding group.

The disadvantage of interleaving block groups is that a write operation which updates sequential blocks will touch different block groups, and require updating multiple coding blocks. In addition, the size and alignment constraints to avoid a read-modify-write cycle are larger. In the non-interleaved case of FIG. 5, for example, in order to avoid a read-modify-write update of a coding block, writes must be at least three blocks and aligned on a three-block boundary. In the interleaved case of FIG. 8, writes must be at least nine blocks and aligned on a nine-block boundary in order to avoid this penalty. However, in both cases, a write of nine blocks will still touch the same number of coding blocks and require the same number of updates.

One possible implementation uses an interleave factor of 4, a block group size of 8, and XOR parity as the error-correcting code (M=1). This arrangement would allow correcting all sequential runs of four UREs in a group of (8*4)=32 blocks. The minimum write size and alignment to avoid a read-modify-write cycle would be 16 KB, assuming a common 512-byte sector size. As with the non-interleaved example above, the error correcting code overhead is ( 1/9)=11%.

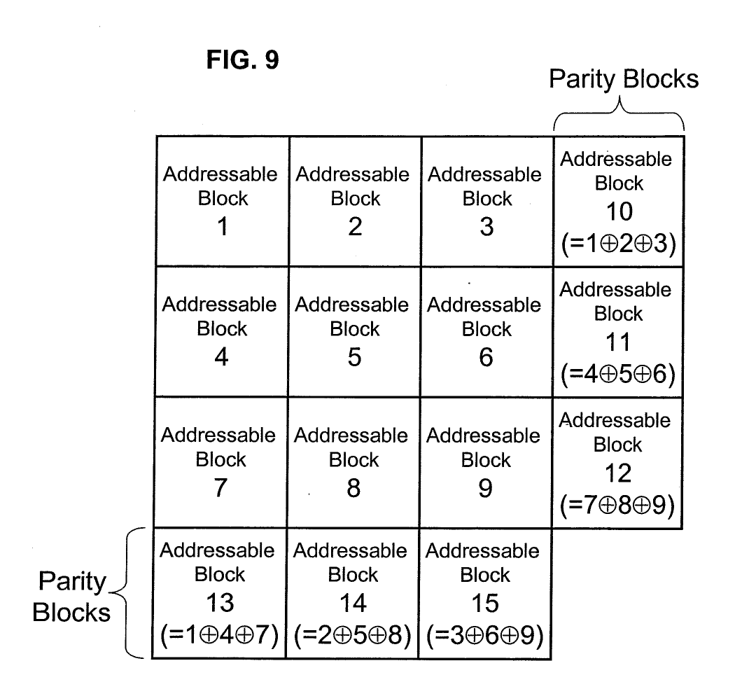

An alternate mechanism to interleaving block groups is to divide the block space up into groups of (N+1)²−1 blocks, and compute both row and column parity in that group of blocks. The example of FIG. 9 shows the data blocks (numbered 1-9) and parity blocks (numbered 10-15) for N=3. As shown in FIG. 9, parity block 10 is calculated as the exclusive OR of addressable blocks A1, A2 and A3 (i.e., A1 ⊕ A2 ⊕ A3). Likewise, parity blocks 11 and 12 are calculated as the exclusive OR of addressable blocks A4, A5, and A6 and addressable blocks A7, A8, and A9, respectively. Parity block 13 is calculated as the exclusive OR of addressable blocks A1, A4, and A7. Likewise, parity blocks 14 and 15 are calculated as the exclusive OR of addressable blocks A2, A5, and A8 and addressable blocks A3, A6, and A9, respectively. It should be appreciated that parity blocks 10-15 (or some combination) may be calculated according to a different error-correcting code scheme, and that a different ratio of data blocks to coding blocks may be used. Moreover, the parity blocks may be arranged relative to the other addressable blocks according to the arrangements in FIG. 4 or 5, or even FIG. 8, or according to another arrangement.

In this arrangement, any consecutive run of N UREs in the group can be repaired, as well as two non-consecutive UREs anywhere in the group, and many combinations of 3 or more non-consecutive UREs. Generally the error correcting code overhead is 2N/(N²+2N). In an example implementation where N=8 (i.e., each row and column is 4 KB, assuming 512-byte sectors), the error correcting code overhead would be 20%. A write that touches fewer than N² data blocks will involve between 1 and N read-modify-write updates to the parity blocks.

The error correcting code may be provided to a client reading data, for the purpose of allowing the client to detect errors between the disk drive and the client. For example, the client may use the error correcting codes to determine whether a network device positioned between the client and the disk drive has corrupted data.

The error-correcting code arrangement and data recovery techniques described herein may be used in conjunction with a RAID-X implementation. For example, a RAID-X implementation may involve distributing data across multiple storage devices, using striping and/or an error-correcting code, such as XOR-based parity or a Reed-Solomon code. Some examples of specific RAID-X formats include RAID-0, RAID-1, RAID-3, RAID-4, RAID-5, RAID-10, RAID-50, etc. In accordance with a RAID-X implementation, the file's data for a given file may be broken-up into separate components (or stripe units), each component may be allocated on a physical storage device with the separate components of the file being stored on different storage devices, and the RAID parity for the file may be computed in accordance with the physical boundaries of the separate components of the file on the different storage devices. Each file can have different RAID parameters (for example, stripe unit size, stripe width, etc.) and can be stored on a different combination of the available storage devices. A file system (implemented, e.g., on manager 10 and client(s) 30 in the example of FIG. 1) may also maintain access to a map indicating the storage devices where the separate components of the file and the corresponding RAID parity information are stored. Moreover, while described above in connection with memory blocks, the error-correcting code may be applied to other storage arrangements. Further, the error-correcting techniques described above may be implemented not only in software, but in firmware or dedicated hardware, or a combination of the foregoing.

As will be appreciated by those skilled in the art that changes could be made to the embodiments described above without departing from the broad inventive concept thereof. It is understood, therefore, that this invention is not limited to the particular embodiments disclosed, but is intended to cover modifications within the spirit and scope of the present invention as defined in the appended claims.

What is claimed is:

1. A method for performing error correction on a single physical storage disk, comprising:
arranging a plurality of addressable blocks on the single physical storage disk into error correction groups, wherein each error correction group comprises N data blocks and M coding blocks, and for each error correction group:
computing, in accordance with the error-correcting code, error-correcting coding data across the N data blocks in the error correction group; and
storing the computed error-correcting coding data in the M coding blocks in the error correcting group;
wherein said arranging, computing and storing steps are performed by a hardware or software component external to the single physical storage disk.

2. The method of claim 1, wherein said error-correcting coding data corresponds to XOR-based parity data.

3. The method of claim 1, further comprising:
receiving an error message if the single physical storage disk is unable to read one or more failed data or coding blocks associated with a given error correction group;
in response to the error message, attempting to read a remainder of the data and coding blocks in the given error correction group; and
if a sufficient number of the remainder of the data and coding blocks and coding blocks are successfully read, computing a corrected version of the one or more failed data or coding blocks from at least part of the remainder of the data and the coding blocks.

4. The method of claim 3, further comprising:
using the corrected version of the one or more failed data or coding blocks to rewrite an unreadable addressable block, optionally to a spare addressable block on the single physical storage disk, thereby repairing a fault associated with the error message.

5. The method of claim 2, wherein M is equal to one and N is selected from the group consisting of: 8, 16 and 256.

6. The method of claim 1, wherein said error-correcting coding data corresponds to Reed-Solomon data, and N and M are selected from the group consisting of:
N=8 and M=2;
N=16 and M=2;
N=64 and M=2; and
N=256 and M=4.

7. The method of claim 1, further comprising detecting a silent read error by:
reading, from the disk, data and coding blocks associated with a given error correction group,
computing an expected value of the one or more coding blocks from the data blocks read from the disk, and
comparing the expected value to the one or more coding blocks read from the disk,
wherein a silent read error is identified if the computed value does not match the one or more coding blocks read from the disk.

8. The method of claim 7, further comprising, if a silent error is detected, reconstructing the object from redundant data on other storage disks.

9. The method of claim 1, further comprising: storing the K*N data blocks of K error correction groups contiguously, followed by K*M coding blocks associated with said K*N data blocks.

10. The method of claim 9, where K is equal to 4, N is equal to 8, and XOR parity is used as the error-correcting code.

11. The method of claim 1, further comprising logically arranging the N data blocks in each error correction group into a rectangular array having rows and columns, and computing the error correcting code across both the rows and columns of the array.

12. The method of claim 1, further comprising interleaving the data blocks and coding blocks from K error correction groups, such that consecutive addressable blocks on the physical disk contain data or coding blocks from different error correction groups.

13. The method of claim 1, further comprising transferring both the data blocks and coding blocks from each error correction group to a host or client machine which is an end-user of the data represented by the error correction groups.

14. The method of claim 1, where M is determined in accordance with a desired failure tolerance of the error correction groups and an error-correcting code.

15. A method for recovering data from a physical storage device in the event of a read error, wherein the storage device stores data organized in a plurality of correction groups, each correction group comprising a plurality of addressable blocks for storing data and an addressable block for storing error-correcting code coding information corresponding to the data of the plurality of blocks of the correction group, the method comprising:
attempting to read data contents of a selected addressable block of the storage device;
if a read error of the physical storage device occurs preventing the selected addressable block from being properly read, then reading the contents of the correction group to which the selected addressable block belongs; and
computing correct data of the selected addressable block using the data contents of the remainder of the addressable blocks of the correction group and error-correcting code information of the correction group.

16. The method of claim 15, further comprising storing the computed correct data in another addressable block.

17. The method of claim 15, wherein the step of attempting to read the data contents of the selected addressable block of the storage device comprises attempting to read the data contents of multiple addressable blocks of the storage device, including the selected addressable block.

18. A method for detecting silent read errors of data stored in a selected addressable block of a physical storage device, wherein the storage device stores data organized in a plurality of correction groups, each correction group comprising a plurality of addressable blocks for storing data and an addressable block for storing error-correcting code coding information corresponding to the stored data of the plurality of blocks of the correction group, the method comprising:
reading data contents of a correction group corresponding to the selected addressable block from the storage device, the data contents including stored data of addressable blocks of the correction group and error-correcting code information of the correction group;
computing error-correcting code information using the data of the plurality of addressable blocks of the correction group;
comparing the computed error-correcting code information to the error-correcting code information read from storage device; and
indicating a silent read error if the computed error-correcting code information does not match the error-correcting code information read from storage device.
